(19) United States
(12) Patent Application Publication
(10) Pub. No.: US 2012/0024918 A1
(43) Pub. Date: Feb. 2, 2012

(54) HOLDER FOR AN ELECTRONIC DEVICE

(75) Inventors: Ron DeCamp, Westminster, CA (US); Mark Thoni, Rancho Santa Margarita, CA (US)

(73) Assignee: Targus Group International, Inc., Anaheim, CA (US)

(21) Appl. No.: 13/192,197

(22) Filed: Jul. 27, 2011

Related U.S. Application Data
(60) Provisional application No. 61/368,047, filed on Jul. 27, 2010.

(51) Int. Cl. A45F 5/00; H05K 7/00

(52) U.S. Cl. 224/267; 248/125.7

(57) ABSTRACT

A holder for portable electronic devices are disclosed. In some embodiments, the holder may include a base configured to sit on a working surface and a securement device configured to releasably secure the portable electronic device. In some embodiments, the holder may include a rotation member coupled to and between the securement device and the base to allow the securement device to rotate in one or more directions relative to the base. In some embodiments, the holder includes a sleeve and is configured to secure the portable electronic device to a forearm of a user.

### RELATED APPLICATIONS

This application claims priority under 35 U.S.C. §119(e) to U.S. Provisional Patent Application No. 61/368,047, filed Jul. 27, 2010, and entitled “HOLDER FOR AN ELECTRONIC DEVICE,” which is herein incorporated by reference in its entirety.

### TECHNICAL FIELD

The present disclosure relates generally to holders for portable electronic devices.

### BRIEF DESCRIPTION OF THE DRAWINGS

Non-limiting and non-exhaustive embodiments of the disclosure are described, including various embodiments of the disclosure with reference to the figures, in which:

FIGS. 1A and 1B illustrate a holder for an electronic device, according to one embodiment.

FIGS. 2A-2C illustrate a front view of a case of a holder, according to one embodiment.

FIGS. 3A and 3B illustrate a back view of a case of a holder, according to one embodiment.

FIGS. 4A-4D illustrate a holder for an electronic device, according to another embodiment.

FIGS. 5A-5E illustrate a holder for an electronic device, according to another embodiment.

FIGS. 6A-6E illustrate a holder for an electronic device, according to another embodiment.

FIGS. 7A-7H illustrate a holder for an electronic device, according to another embodiment.

FIGS. 8A-8C illustrate a holder for an electronic device, according to another embodiment.

FIGS. 9A-9E illustrate a split cam rotation member, according to one embodiment.

### DETAILED DESCRIPTION OF PREFERRED EMBODIMENTS

The proliferation of portable electronic devices (PEDs), including notebook and tablet computers, PDAs, and smart phones, has placed more computing power into the hands of users than the computing power of early computers that occupied an entire room. This portable computing power has enhanced both personal and business mobile productivity, or productivity away from a traditional office.

Touchscreen technology and display technology has further revolutionized mobile productivity. Touchscreen technology allows data to be quickly and efficiently entered with a single hand, and even with a single touch. To allow display flexibility for applications that are more easily viewed in landscape orientation than in portrait orientation, PEDs may automatically adjust the display when rotated from a portrait orientation to a landscape orientation.

The flexibility and portability of PEDs are not without challenges. The sleek, lightweight design of many PEDs may limit the ability to secure a PED while operating it. For example, the design of a PED may prevent a user from firmly or easily grasping the PED with one hand. Prolonged use may tire the user's hand that is used to secure the device. The Apple® iPad™, for example, is a tablet computer designed for portability. The iPad may not be easily secured in one hand and prolonged use of the iPad may tire the user's securing hand.

The present disclosure provides embodiments of holders for a PED, such as an iPad. In some embodiments, the holder may be configured to prop the PED in an upright position on a horizontal or nearly horizontal working surface, such as on a table, desk, or the like. As used herein, the term upright position means a position in which a plane of a back surface of a PED (e.g., a side of the iPad opposite the touchscreen) is positioned at an angle with respect to a horizontal plane (e.g., the horizontal or nearly horizontal working surface). For example, the angle between the back surface of the PED and the working surface may be greater than 0° and less than 180°. Generally, the angle between the back surface of the PED and the working surface may be greater than 0° and less than 90°, such that the screen of the PED is presented to the user at an ergonomic viewing angle with the user looking horizontally at the screen or at a downward angle at the screen. In some embodiments, rotation of the PED in the upright position allows the angle between the back surface of the PED and the working surface to vary through a range of angles. For example, the angle may range between 0° and 90°. In still other embodiments, the angle may be between 30° and 90°. In still other embodiments, the angle may be between 45° and 90°. In still other embodiments, the angle may be between 60° and 90°. In still other embodiments, the angle may range between 45° and 85°. In still other embodiments, the angle may range between 50° and 80°. In still other embodiments, the angle may range between 65° and 75°.

In some embodiments of the present disclosure, a measure of convenience and efficiency may be obtained by providing a holder of a PED that facilitates securement of the PED while affording full functionality of a touch screen and an ability to use the PED in both a portrait orientation and a landscape orientation.

The embodiments disclosed herein are described as being configured to be used with an iPad. An ordinarily skilled artisan appreciates that the embodiments are not limited to use with an iPad and can be configured to hold and support any of a variety of PEDs and thus the present disclosure is not limited by the embodiments disclosed nor limited to use with an iPad. The term “iPad” as used herein refers to an iPad and to any of a variety of suitable portable electronic devices.

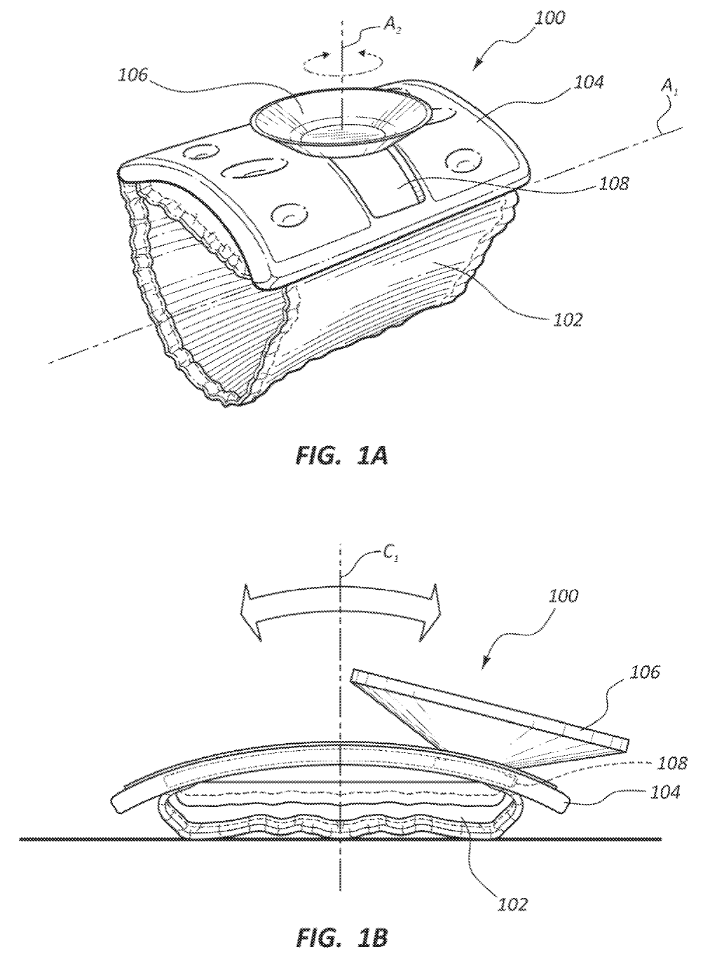

FIGS. 1A and 1B illustrate a holder 100 for an electronic device according to one embodiment of the present disclosure. The holder 100 may comprise a sleeve 102, a mounting base 104, and a securement device 106. The sleeve 102 may be formed of a stretchable and/or elastic material. The sleeve 102 may be constructed and configured to be coupled to the mounting base 104. The mounting base 104 may comprise a shell, which may be molded to correspond to the contour of, for example, a user's forearm. The sleeve 102 and the mounting base 104 may be coupled together with stitching, or any suitable method or device for attaching a flexible cloth or cloth-like material (e.g., the sleeve 102) to a rigid material or shell (e.g., the mounting base 104), including but not limited to glue, adhesive, hooks and loops, and snaps. The sleeve 102 can be placed on a forearm of a user to secure the mounting base 104 to the forearm. The user can insert an arm through the sleeve 102 to thereby secure the mounting base 104 to the user's forearm.

The mounting base 104 may comprise a shell configured to be positioned on the top of the user's arm when the arm is inserted through the sleeve 102. The shell may be constructed and configured to support the securement device 106. The mounting base 104 may further include a track 108 to allow positioning of the securement device 106 to be adjusted relative to the mounting base 104. In the illustrated embodiment, the track 108 is oriented in a direction transverse to a longitudinal axis A1 of the sleeve 102 (and a longitudinal axis of the mounting base 104). Accordingly, the track may enable at least partial rotation of the securement device 106 about a longitudinal axis of the sleeve. The partial rotation along the track may adjust the position of the securement device 106 forward or backward relative to a centerline C1 of the mounting base 104, as shown in FIG. 1B. In other embodiments, the track may be configured differently, such as in a direction parallel to the longitudinal axis of the sleeve 102 (and mounting base 104).

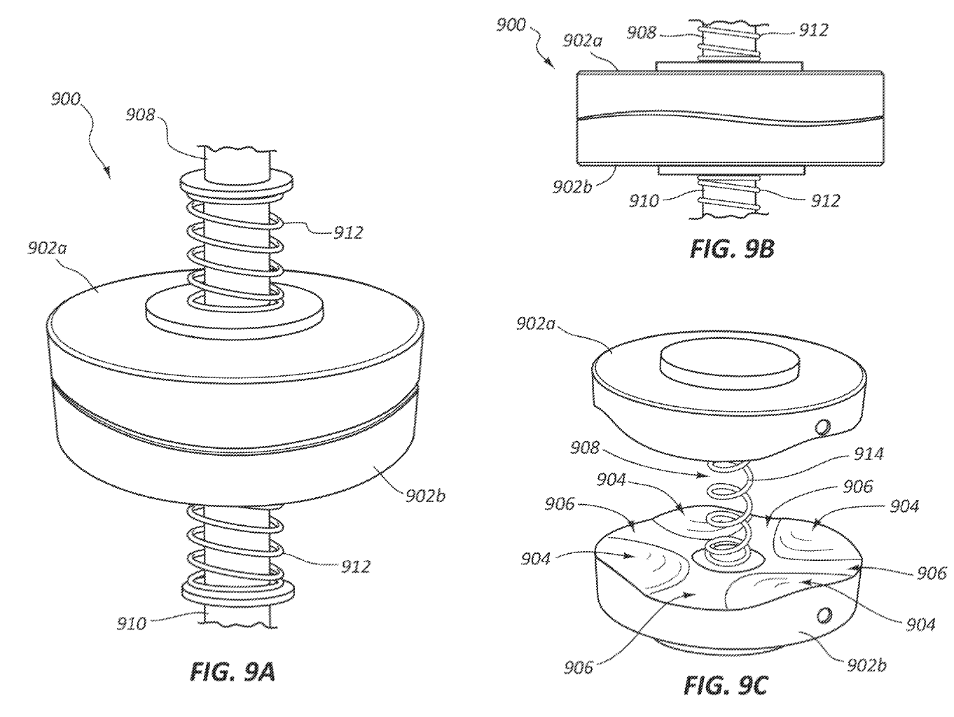

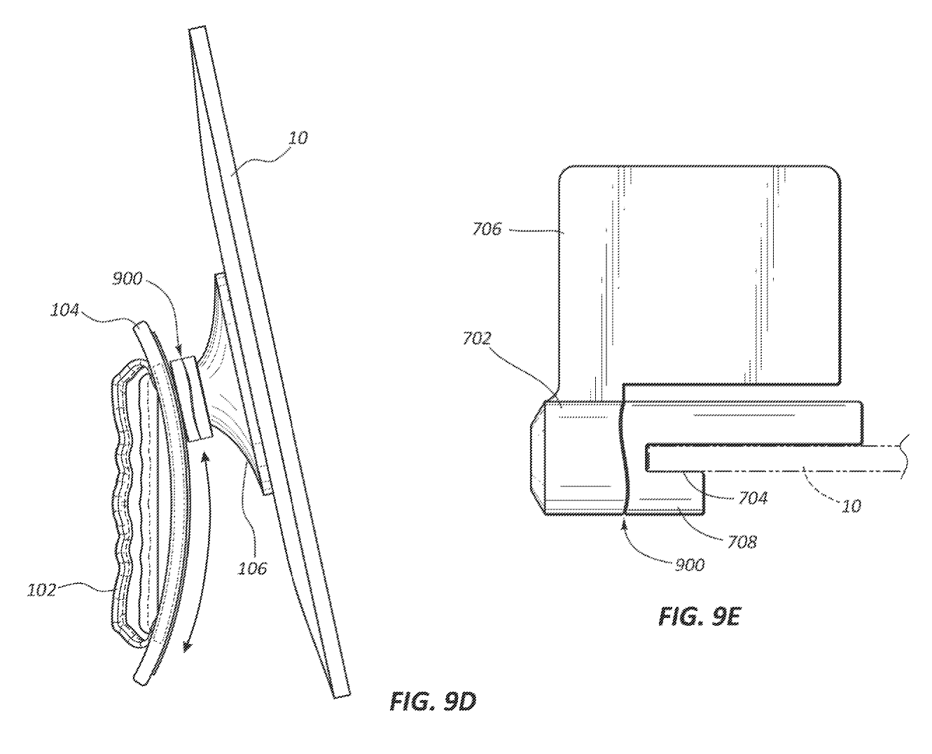

The securement device 106 of the illustrated holder 100 is a suction cup configured to releasably attach to the back of a case or directly to the back of an iPad or other PED (not shown in the figure). In other embodiments the securement device 106 may comprise any appropriate mechanism for attaching an electronic device or case to the mounting base 104. The securement device 106 and/or the mounting base 104 may be configured such that the securement device 106 is separately pivotable to allow rotation and/or pivoting of an iPad attached thereto about an axis A2 that is transverse to the longitudinal axis A1 of the sleeve. The rotation may be enabled by a rotation member, such as a ratcheting swivel. An example of a rotation member is shown in FIGS. 9A-9E and described below with reference to the same. The rotation of the securement device 106 can allow the iPad to be positioned in a portrait orientation and in a landscape orientation. The rotation of the securement device 106 may be accomplished by a ratcheting swivel, a ball and socket, or any suitable rotatable rotation member. Alternatively, the holder 100 may be rotatable in the sense that the securement device can be detached from the iPad (or case) and rotated relative to the iPad to achieve a desired orientation.

The securement device 106 may also be able to tilt relative to the shell. The tilt may be separate and independent from rotation about axis A2 and from repositioning along the track 108 (or rotation about the longitudinal axis A1 of the sleeve 102).

FIG. 1B illustrates that the sleeve 102 can be folded or otherwise tucked into a cavity of the mounting base 104, thereby allowing the mounting base 104 to function as a stand to support the iPad in an upright position. The mounting base 104 may contact a surface upon which the holder 100 is placed and provide a stable stand for an iPad. The tilt of the securement device 106 and/or rotation of the securement device 106 about the longitudinal axis A1 of the sleeve 102 may facilitate positioning the iPad in a partially upright position.

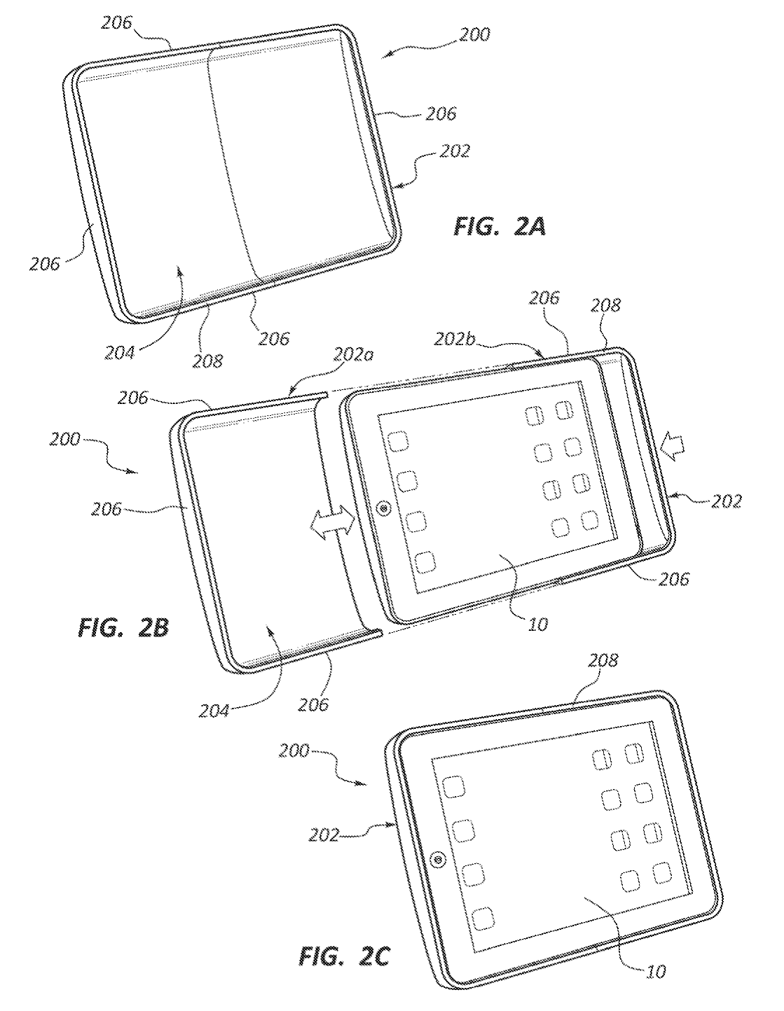

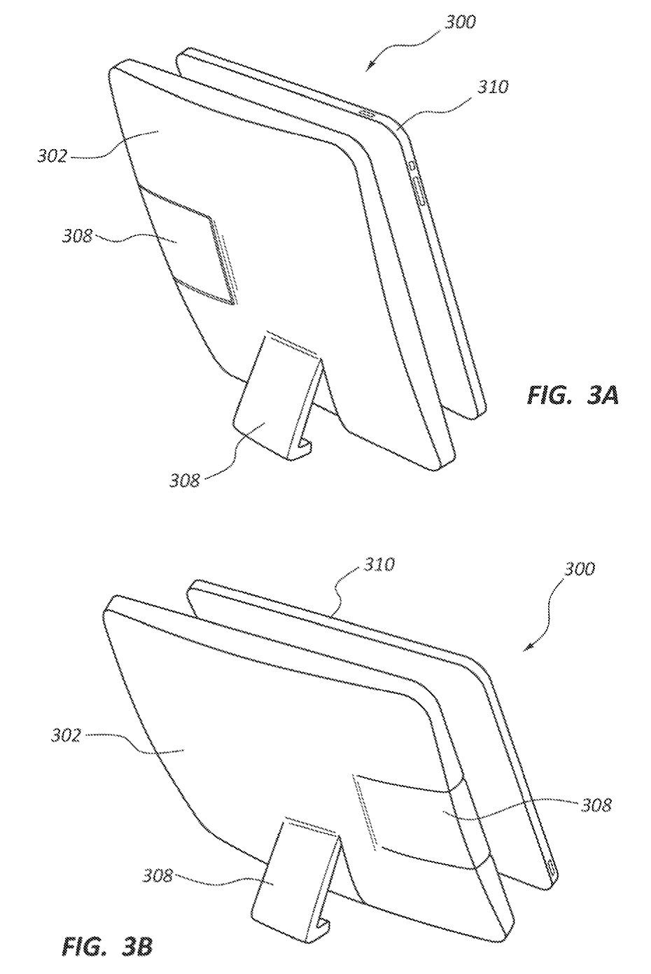

As can be appreciated, the holder 100 can further comprise a case (not shown) configured to receive, secure, and carry an iPad or another electronic device. The case may secure the iPad, while exposing the touch-screen surface to allow user manipulation of the touchscreen for operating the iPad. The case may provide one or more of a back, one or more sides, and a front, to secure and protect an electronic device. The securement device 106 can be configured to attach to the case or may be permanently affixed to the case. One embodiment of a case for an iPad is discussed below with reference to FIGS. 2A-2C, and another embodiment is discussed below with reference to FIGS. 3A and 3B.

FIGS. 2A-2C illustrate a front view of a holder 200, showing insertion of an iPad 10 into a case 202 of the illustrated embodiment. As shown, the case 202 may be shaped and configured to receive and fittingly secure the iPad 10, while exposing the touchscreen for user manipulation to operate the iPad 10. The case 202 may provide one or more of a back 204, one or more sides 206, and a front (not depicted), to secure and protect the iPad 10. The case 202 may have a depth to accommodate the thickness of the iPad 10. In other words, the sides 206 may have a width sufficient to accommodate the thickness of the iPad 10 or any other similar electronic device. The case 202 may also have a shape substantially similar to the shape of the iPad 10, such that a portion of the case 202, such as a lip 208 (or rail), may fittingly secure the iPad 10. For example, a side 206 of the case 202 may form a lip 208 that wraps around the edge of the iPad 10 from back to front. The lip 208 may be positioned around a portion of one or more edges of the front surface of the iPad 10, thereby securing the iPad 10 while leaving the touchscreen substantially exposed for a user to manipulate. The case 202 may comprise two pieces 202a, 202b that slide together and/or lock in place around the iPad 10, as depicted in FIG. 2B, to secure the iPad 10 as shown in FIG. 2C. The two pieces 202a and 202b may be attached to one another via one or more rails, bars, or the like. Alternatively, pieces 202a and 202b may be entirely separate pieces.

FIGS. 3A-3B illustrate a back perspective view of a case 302 of a holder 300 according to one embodiment of the present disclosure. The case 302 may include a one or more kickstands 308 configured to to allow the case 302 to also function as a stand. The one or more kickstands 308 may be recessed into the case 302 when not in use, and may rotate out from the case 302 for use to prop the case 302, as illustrated. The one or more kickstands 308 allow the case to operate as a stand to support an iPad 10 (FIGS. 2B and 2C) in an upright position. A first kickstand 308 may prop the case upright in a landscape orientation as shown in FIG. 3A and a second kickstand 308 may prop the case upright in a portrait orientation as shown in FIG. 3B.

The case 302 may also include a cover 310 configured to be positioned over an iPad 10 (FIGS. 2B and 2C) inserted into the case 302 to substantially enclose the iPad 10. The cover 310 may, for example, snap to the case 302. The cover 310 can be used to protect the iPad 10 when not in use. In another embodiment, the cover may comprise a transparent window through which a user can manipulate the iPad 10, and thus the cover can remain positioned over the iPad 10, both during use and when not in use, to protect the iPad 10. The window may be selectively openable. In another embodiment, the window may be an opening in the cover 310 such that the window is permanently open to allow a user direct access to the touchscreen of the iPad 10.

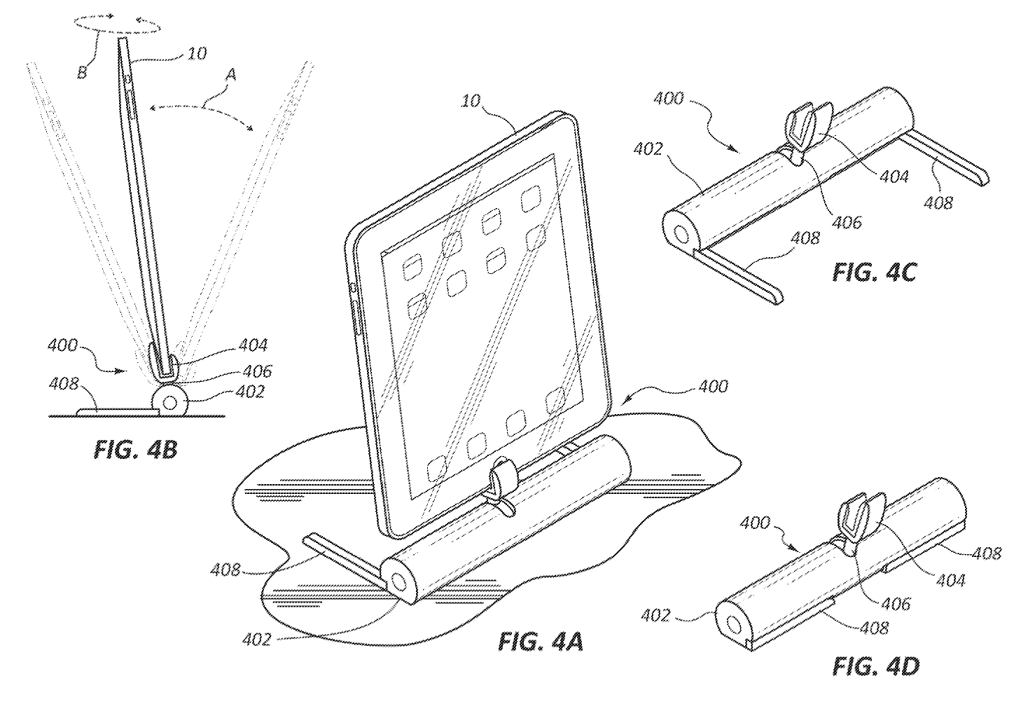

FIGS. 4A-4D illustrate a holder 400 for an electronic device according to another embodiment of the present disclosure. The holder 400 may include a weighted base 402, a securement device 404, and a coupling member 406. The weighted base 402 may be a flattened cylindrical shape sufficiently weighted to support the weight of an iPad 10 when inserted into the securement device 404 in an upright position. A longitudinal axis of the cylinder extends parallel to a working surface on which the weighted base 402 may be positioned, and a portion of the cylinder may be flattened to limit the weighted base 402 from rolling on the working surface. The weighted base 402 may further include feet 408 that may provide additional support to limit the base 402 from rolling. The feet 408 may be configured to be oriented in an extended position, as shown in FIG. 4C and a storage position, as shown in FIG. 4D. For example, the feet 408 may rotate relative to the base 402 so as to retract into the base 402.

The weighted base 402 may also comprise a coupling member 406 to couple the securement device 404 to the weighted base 402 in a manner that allows the securement device 404 to be rotatable relative to the weighted base 402. In one embodiment, the securement device 404 is rotatable in two directions relative to the weighted base 402. For example, the securement device 404 may pivot around a longitudinal axis of the weighted base 402, as depicted by the directional arrow A, and also may rotate around an axis extending radially from, or perpendicular to, the longitudinal axis of the weighted base 402, as depicted by the directional arrow B.

The securement device 404 may comprise a clip 406 configured to releasably secure to a bottom edge of an iPad 10. The bottom edge may be an edge closest to the working surface upon which the base member may be resting and may change according to the orientation of the device. The iPad 10 may be secured in the clip 406 and supported in an upright position. The iPad 10 can be easily removed from the clip 406, rotated within the plane of the screen of the iPad 10 as desired, and reinserted into the clip 406 to be presented in either a portrait orientation or a landscape orientation. As can be appreciated, the holder 400 may further comprise a case to receive, secure, and carry the iPad 10, and the securement device 404 can be constructed and arranged to couple to and secure the case to thereby support the iPad 10 in an upright position. The clip 406 may comprise a rigid, flexible material and may be configured such that its width is slightly less than that of an iPad so as to accommodate a clamping or friction fit grip between the clip 406 and the iPad.

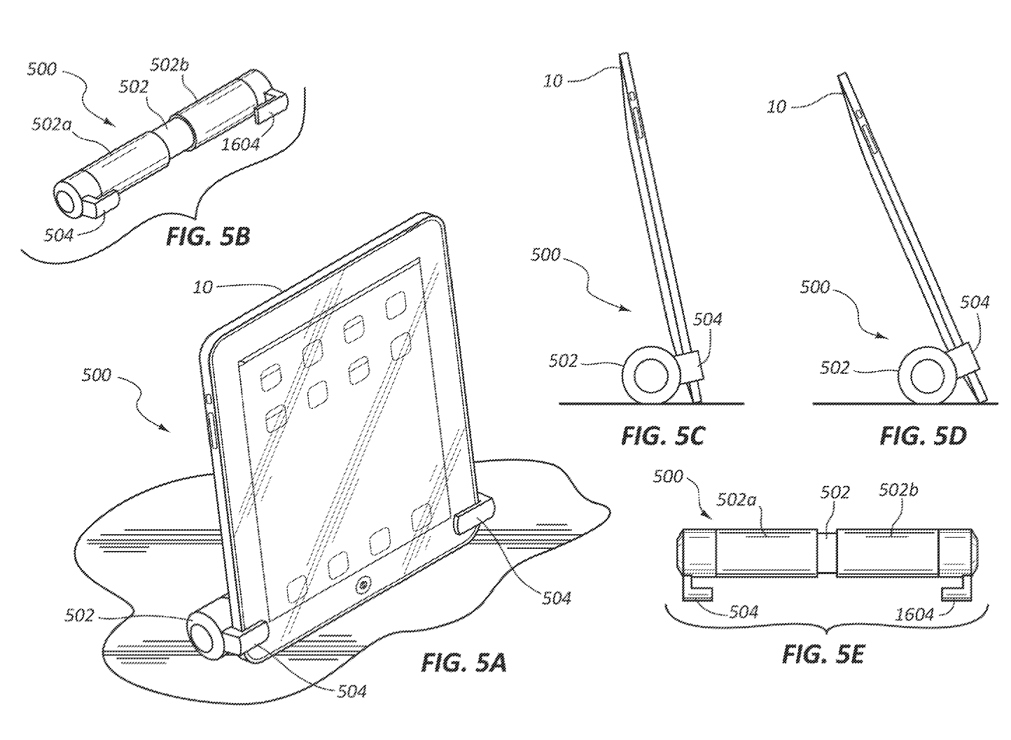

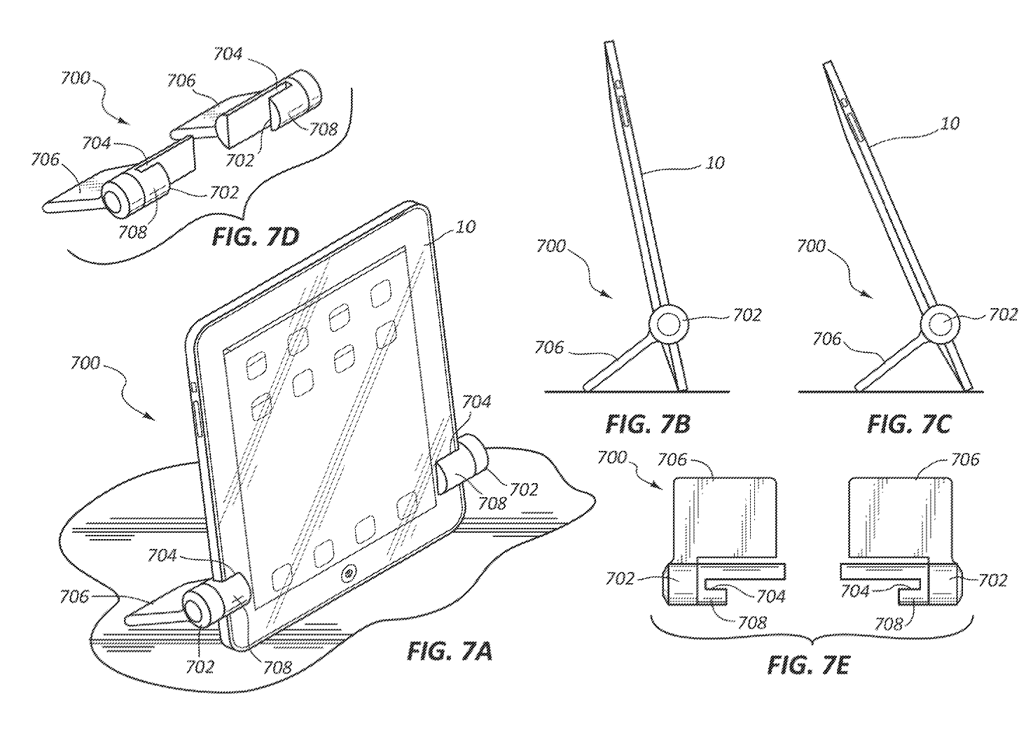

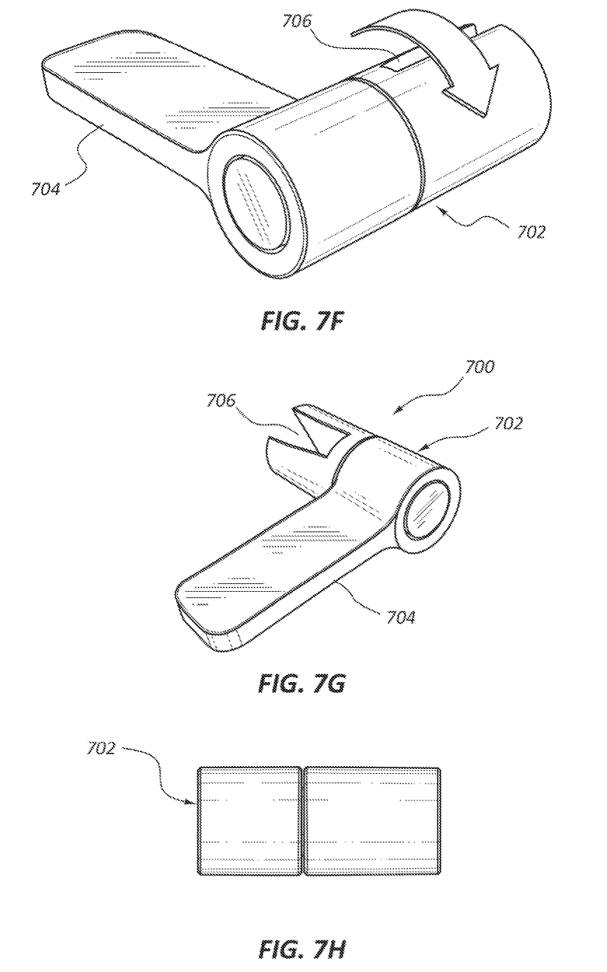

FIGS. 5A-5E illustrate a holder 500 for an electronic device according to another embodiment of the present disclosure. The holder 500 includes a base member 502 and two securement devices 504. The base member 502 may be an elongate, cylindrical or semi-cylindrical shape having a first end configured to be positioned proximate to a first side of an iPad 10 and a second end configured to be positioned proximate to a second side of the iPad 10. The base member 502 is shown alone (without an iPad 10) in FIG. 5B. The length of the base member 502 may be adjustable to conform to the width of an iPad 10 in a portrait orientation and also to conform to the width of an iPad in a landscape orientation. For example, the base member 502 may comprise three pieces, such that two base pieces 502a, 502b nest together with a third base piece 502c in a telescoping fashion, as shown in FIG. 5E. In another embodiment the holder may comprise two base members 502, such that each base member corresponds to one of the securement devices 504, similar to the embodiment of FIGS. 7A-7E discussed below.

Each of the securement devices 504 may be clip members configured to secure to opposite sides of the base member 502. The clip members 504 and base member 502 may be configured so that the clip members 504 can releasably attach to an edge of an iPad 10, as shown in FIG. 5A. The clip members 504 may allow the iPad 10 to be inserted by sliding into the clip members 504 from the top, in a direction parallel to a plane of a surface of the iPad 10. In another embodiment, the clip members 504 may be constructed and arranged to receive an iPad 10 inserted by pushing the iPad into the clip members 504 in a direction substantially transverse to a plane of the screen of the iPad 10.

When an iPad is inserted into the holder 500, the clip member 504 may be positioned on the side edges near the bottom (closest to a surface on which the iPad is to be propped), and the iPad may be supported in an upright position by the clip members 504 and base member 504. As can be appreciated, the clip members 504 may be rotatable around a longitudinal axis of the base member 502 to allow the iPad 10 to be tilted, as shown in FIGS. 5C and 5D.

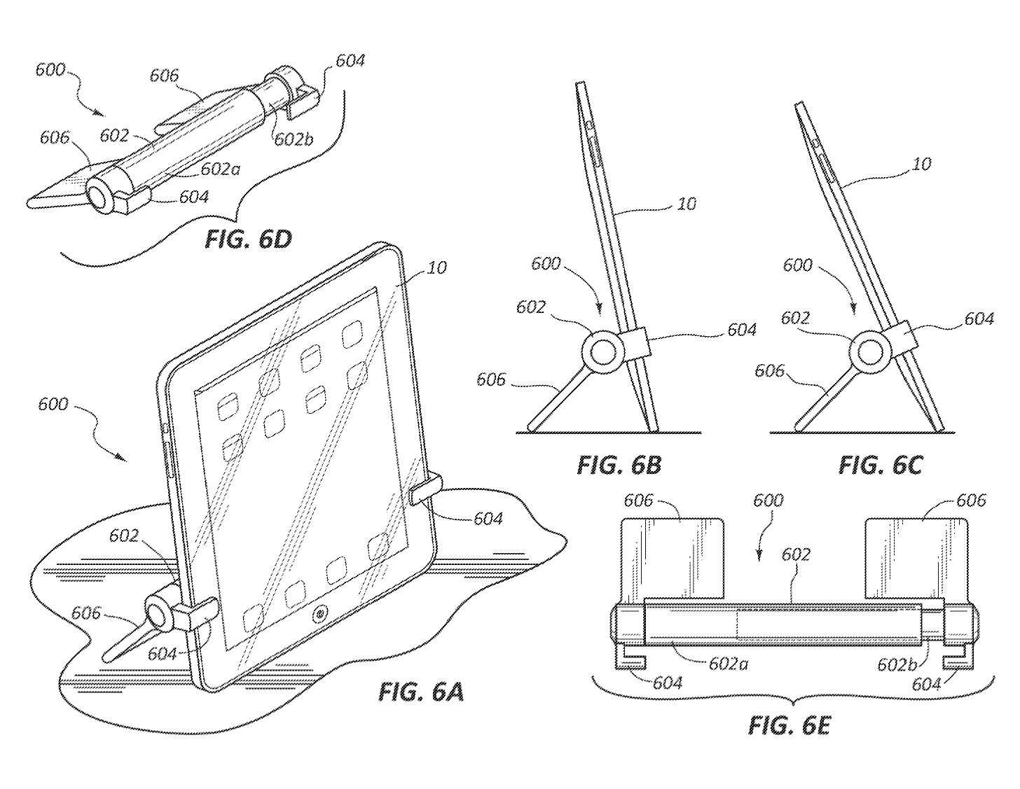

FIGS. 6A-6E illustrate a holder 600 for an electronic device according to another embodiment of the present disclosure. The holder 600 includes a base member 602 and two clip members 604, similar to the holder 500 of FIGS. 5A-5C. The length of the base member 602 may be adjustable to conform to the width of an iPad 10 in a portrait orientation and also to conform to the width of an iPad in a landscape orientation. For example, the base member 602 may comprise two base pieces 602a, 602b nested together in a telescoping fashion. The clip members 604 may support and secure the iPad 10. The base member 602 may further comprise a foot 606 (or plurality of feet) extending radially from a cylindrical portion of the base member 602 and constructed and arranged to prop the base member 602 and limit rolling of the base member 602 on a working surface on which the holder 600 may be placed. Alternatively, the base member 602 may be elevated above the surface and only the foot member 602 may function as a support to prop up the iPad 10. FIGS. 6A, 6B, and 6C illustrate this configuration with the base member 602 elevated above the working surface positioned at a distance from a bottom edge and along a length of the iPad 10 and the foot member 606 propping the iPad 10 with the bottom edge on the working surface. FIG. 6D illustrates the holder 600 without an iPad 10, and shows two foot members 606 extending radially from a cylindrical portion of the base member 602.

In one embodiment, the foot member 606 may comprise a single rod extending radially from a portion of the base member 602. For example, the foot member 606 may be positioned at an outer edge of the base member 602, or two foot members 606 may be positioned at each of the outer edges of the base member 602 The foot member 606 may also be positioned on the base member 602 closer toward the center of the iPad 10 or other electronic device and a single foot member, if sufficiently wide, may be used if desired. In another embodiment, the foot member 606 may comprise a plate that extends at least a portion of a width of the iPad 10. In other words, the foot member 606 may be solid and extend across at least a portion of the back of an iPad inserted into the holder 600. In still another embodiment, the foot member 606 may comprise a frame formed by a bar configured in a “U” shape. The bar of the frame may extend radially from the base member 602 and extend substantially across at least a portion of the back of an iPad 10 inserted into the holder 600.

FIGS. 7A-7G illustrate a holder 700 for an electronic device according to another embodiment of the present disclosure. The holder 700 may include two base members 702 and two securement devices 704. The first base member 702 is constructed and arrange to couple to a first side of an iPad 10 and/or a case and a second base member 702 is constructed and arranged to separately couple to a second side of an iPad, as shown in FIG. 7A. Together the first and second base members function as stand for an iPad 10, or other electronic device, to prop the iPad 10 in a substantially vertical position. Each base member 702 may comprise a foot 706 and a securement device 704. The foot 706 may extend radially from a cylindrical portion of the base member 702 to secure the base member 702 at a substantially fixed position on a surface.

The securement device 704 may be a clip member. The clip member 704 may be cylindrical in shape and may be positioned coaxial with and/or integrated with the cylindrical portion of the base member 702 and is configured to receive and secure an edge of an iPad. In the illustrated embodiment, the clip member 704 is configured as a slot into which the iPad can be slid or inserted from the top. The iPad can be inserted into the clip member 704 and supported at a slight angle in an upright position. In another embodiment, the clip member 704 can also comprise a biased securement component 708 that forms the front portion of the slot and that may be shaped and configured to retract toward the outer edge of the base member 702 when force is applied to the front of the biased securement component 708. Accordingly, the biased securement component 708 allows an iPad 10 or other electronic device to be inserted by pressing the iPad 10 into the clip members 704 in a direction perpendicular to the direction of the slot.

FIGS. 7F-7G illustrate another embodiment of a base member 702f of a holder 700 for an electronic device. As can be appreciated, the base member 702 may be constructed and arranged to be used by itself or in conjunction with another base member 700 having a mirror-image configuration to secure an opposite bottom corner of the iPad.

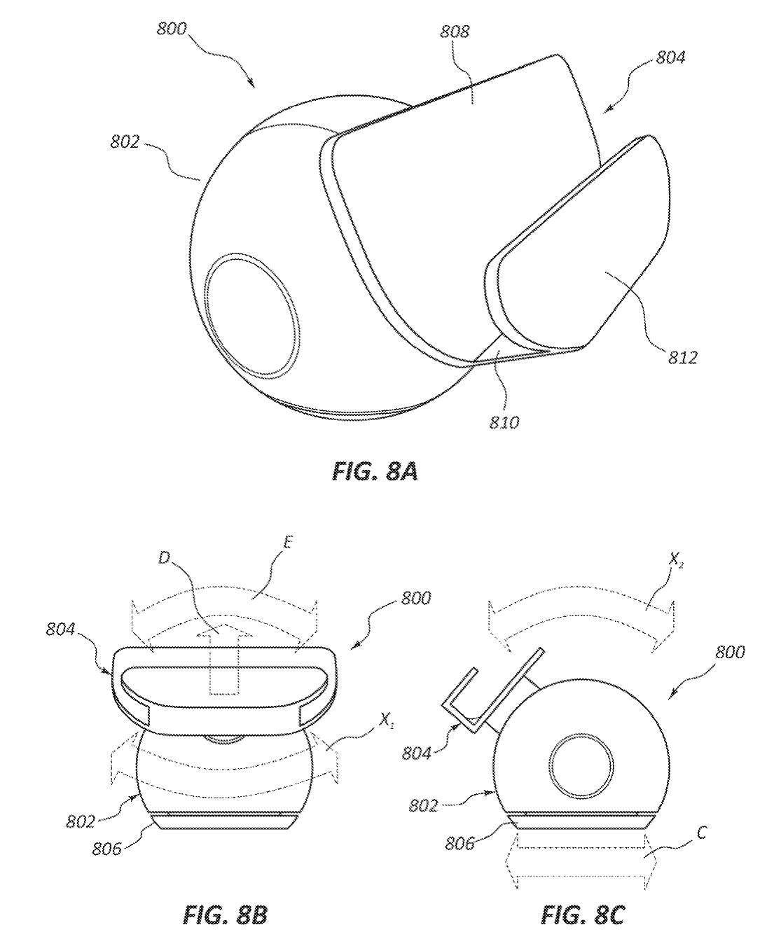

FIGS. 8A-8C illustrate a holder 800 for an electronic device according to another embodiment of the present disclosure. The holder 800 may comprise a base member 802 and a securement device 804. The base member 802 in the illustrated embodiment may comprise a substantially spherical shape having a flattened bottom side. The base member 802 may further comprise a rotating base 806 configured to allow the base member to rotate 804 about a vertical axis, as shown by arrow C.

The securement device 804 may be a tray configured to support an iPad in an upright position in either a portrait orientation or a landscape orientation. The tray 804 may comprise a back 808 to support the back of an iPad inserted into the tray 804, a bottom 810 to support the bottom edge of an iPad inserted into the tray 804, and a front 812 to prevent the iPad from sliding forward out of the tray 804. The tray 804 may be coupled to the spherical base member in a slidable manner so as to adjust the tilt of the tray 804. In other words, the tray 804 may slide relative to the surface of the spherical base member 802, as shown by arrow D, and thereby adjust the tilt of the back 808 of the tray 804. The tray 804 may also be coupled to the base member 802 in a pivotable manner, such that the tray can rotate about an axis perpendicular to the plane of the tray back 808, as shown by arrow E.

FIGS. 9A-9C illustrate a split cam rotation member 900, as may be used in various of the other embodiments described herein. The rotation member 900 may be substantially any cylindrical shape (e.g., a long shaft, a short cylinder similar to a hockey puck, etc.) and may comprise two complementary halves 902a, 902b configured to rotate relative to each other and interact so as to create one or more locking positions. The complementary surfaces of the halves 902a, 902b may comprise one or more protrusions 904 and one or more depressions 906 to implement a locking position. The protrusions 904 of a first half 902a may complement and conform to the depressions 906 of a second half 902b, as shown in FIG. 9B. Similarly, the protrusions 904 of the second half 902b may complement and conform to the depressions 906 of the first half 902a. As the first half 902a rotates relative to the second half 902b, the protrusions 904 of the first half 902a may rotate between non-locking positions (in which the protrusions 904 of the first half 902a abut the protrusions 904 of the second half 902b) and locking positions (in which the protrusions of the first half 902a abut the depressions of the second half). The protrusions 904 and depressions 906 may alternate as shown.

In the illustrated embodiment, the protrusions 904 may have a rounded shape and be configured such that a first protrusion 904 on a first half 902a allows a second protrusion 904 on the opposing second half 902b to smoothly rotate over and past the first protrusion as the halves 902a, 902b rotate relative to one another. Similarly, the depressions 906 may have a rounded shape. Moreover, the transition from a protrusion 904 to a depression 906 may be seamless and continuous to form a gentle rounded surface as illustrated. Accordingly, the halves 902a, 902b can easily be rotated relative to one another, and thereby transitioned between locking positions, while the halves 902a, 902b are in abutment to one another and without being separated.

In still other embodiments, the protrusions 904 may be jagged, or not have a rounded shape. For example, the protrusions may comprise complementary teeth. The teeth may be triangular in shape, alternating between a protrusions and depressions. In such an embodiment, the halves 902a, 902b may need to be pulled apart and separated before rotation can occur, In another embodiment, the transition from protrusion 904 to depression 906 may be more pronounced and in even non continuous, such that there is a separation between each protrusion 904 and depression.

In the illustrated embodiment, each half 902a, 902b comprises four protrusions and four depressions. Accordingly, the split cam rotation member 900 comprises four locking positions. The four locking positions may each correspond to ninety degrees of rotation. As can be appreciated, additional protrusions 904 and depressions 906 may be provided so as to allow additional locking positions at smaller degrees of rotation. Moreover, fewer protrusions 904 and depressions 906 may be provided as well to provide fewer locking positions.

The split cam rotation member 900 may further comprise a connecting member 908, such as a rod or elastic piece, configured as an axis about which the halves 902a, 902b rotate. The connecting member 908 may also secure the halves 902a, 902b relative to one another. In one embodiment, the connecting member 908 may include one or more biasing members configured to urge the first half 902a and second half 902b together. For example, the connecting member 908 may pass through the two halves 902a, 902b and be spring-loaded with springs 912 on the outside of the two halves 902a, 902b to push the two halves 902a, 902b together. Alternatively, the connecting member itself may comprise a biasing member, such as a spring 914 or an elastic material, that may provide a biasing force. The biasing force may be provided to urge the halves 902a, 902b toward one another The biasing force may also urge the split cam rotation member 900 toward a locking position (i.e., by urging the protrusions 904 of the first half 902a toward a position abuting the depressions 906 of the second half 902b and vice versa). In another embodiment, an external force, such as for example gravity, may provide a biasing force to urge the halves 902a, 902b toward one another.

FIG. 9D illustrates a split cam rotation member 900 as a component of holder 100 of FIGS. 1A and 1B. The rotation member 900 couples a securement device 106 to a mounting base 104 such that the securement device 106 can rotate relative to the base 104 and the sleeve 102. The securement device 106 is configured to couple to the back of an iPad 10 such that the iPad 10 can also rotate relative to the base 104. The rotation member 900 provides a plurality of locking positions such that the sleeve 102 and/or base 104 tends to be rotationally oriented relative to the iPad 10 at a position corresponding to one of the locking positions.

Similarly, FIG. 9E illustrates a split cam rotation member 900 as a component of holder 702 of FIG. 7E. The rotation member 900 functions to provide a plurality of locking positions as the case is rotated about a base member 702 to tilt the case, for example, toward and away from a user.

It will be appreciated and understood by those having skill in the art that changes may be made to the details of the above-described embodiments without departing from the underlying principles disclosed herein. Any suitable combination of various embodiments, or the features thereof, is contemplated.

Throughout this specification, any reference to “one embodiment,” “an embodiment,” or “the embodiment” means that a particular feature, structure, or characteristic described in connection with that embodiment is included in at least one embodiment. Thus, the quoted phrases, or variations thereof, as recited throughout this specification are not necessarily all referring to the same embodiment. Similarly, it should be appreciated that in the above description of embodiments, various features are sometimes grouped together in a single embodiment, figure, or description thereof for the purpose of streamlining the disclosure. This method of disclosure, however, is not to be interpreted as reflecting an intention that any claim require more features than those expressly recited in that claim. Rather, inventive aspects may lie in a combination of fewer than all features of any single foregoing disclosed embodiment.

We claim:

1. A holder for a portable electronic device comprising:
a base;
a securement device coupled to the base and configured to releasably secure the portable electronic device to the base; and
a sleeve of flexible material coupled to the base and configured to be positioned on a forearm of a user to secure the base to the forearm of the user and thereby secure the securement device and portable electronic device relative to the forearm of the user.

2. The holder for a portable electronic device of claim 1, further comprising a rotation member coupled to the base and the securement device, the rotation member rotatably coupling the securement device to the base, the rotation member configured to enable rotation of the securement device and the portable electronic device relative to the base.

3. The holder for a portable electronic device of claim 1, wherein the rotation member is a split-cam rotation member.

4. The holder for a portable electronic device of claim 1, wherein the rotation member comprises a first portion coupled to the securement device and a second portion coupled to the base.

5. The holder for a portable electronic device of claim 1, wherein the rotation member comprises a track configured to enable the securement device to rotate about an axis of the base.

6. The holder for a portable electronic device of claim 1, wherein the rotation member is configured to lock into one or more predetermined relative rotational orientations of the holder and the support, and wherein at least one of the one or more predetermined relative rotational orientations is a portrait orientation and at least one of the one or more predetermined relative rotational orientations is a landscape orientation.

7. The holder for a portable electronic device of claim 1, wherein the base is configured to rest on a working surface and position the securement device to support the portable electronic device in an upright position;

8. The holder for a portable electronic device of claim 1, wherein the base is configured to enable adjustment of the position of the securement device relative to the base.

9. The holder for a portable electronic device of claim 8, wherein the base is configured to enable the securement device to rotate in one or more directions about a longitudinal axis of the sleeve.

10. The holder for a portable electronic device of claim 8, wherein the base comprises a track to enable the securement device to shift position relative to the base at least one of forward of a centerline of the base and backward of the centerline of the base.

11. A holder for a portable electronic device comprising:
a base configured to sit on a working surface and having a longitudinal axis parallel to the working surface;
a securement device coupled to the base and configured to releasably secure the portable electronic device to the base and to support the portable electronic device in an upright position,
wherein the securement device is configured to rotate about the longitudinal axis of the base to adjust a viewing angle of a viewer of a screen of the portable electronic device.

12. The holder for a portable electronic device of claim 11, wherein the securement device is configured to rotate on an axis transverse to the longitudinal axis of the base.

13. The holder for a portable electronic device of claim 11, wherein the base comprises a cylindrical shape, wherein a longitudinal axis of the cylindrical shape configured to be positioned parallel to the working surface.

14. The holder for a portable electronic device of claim 11, wherein the base comprises a flattened cylindrical shape having a flattened surface configured to rest upon the working surface to restrict rotation of the base on the working surface, a longitudinal axis of the flattened cylindrical shape configured to be positioned parallel to the working surface.

15. The holder for a portable electronic device of claim 11, wherein the base is weighted to support the weight of the portable electronic device when inserted into the securement device in an upright position.

16. The holder for a portable electronic device of claim 11, wherein the securement device comprises a clip configured to releasably secure to a bottom edge of a portable electronic device.

17. The holder for a portable electronic device of claim 11, wherein a length of the base is adjustable to conform to a width of a portable electronic device in a portrait orientation and to conform to a width of a portable electronic device in a landscape configuration.

18. The holder for a portable electronic device of claim 11, wherein the base comprises feet to restrict movement of the base on the working surface.

19. The holder for a portable electronic device of claim 18, wherein the feet are rotatable relative to the base between a retracted position that does not restrict movement of the base and a protruding position that restricts movement of the base on the working surface.

20. The holder for a portable electronic device of claim 11, further comprising a coupling member to couple the securement device to the weighted base in a manner that allows the securement device to be rotatable relative to the weighted base.

21. The holder for a portable electronic device of claim 11, wherein the holder comprises a plurality of securement devices.

22. The holder for a portable electronic device of claim 11, wherein the securement device is configured to receive the portable electronic device by sliding it into the securement device from above in a downward direction.

23. The holder for a portable electronic device of claim 11, wherein the securement device is configured to receive the portable electronic device by pushing it into the securement device in a direction substantially transverse to a plane of a screen of the portable electronic device.

24. The holder for a portable electronic device of claim 11, wherein the securement device comprises a clip.

25. The holder for a portable electronic device of claim 11, wherein the securement device comprises a slot.

26. The holder for a portable electronic device of claim 11, wherein the base has a spherical shape having a flattened bottom side.

27. The holder for a portable electronic device of claim 26, wherein the securement device is coupled to the spherical base in a slidable manner so as enable a tilt of the securement device to be adjustable.

28. The holder for a portable electronic device of claim 11, wherein the securement device comprises a tray.
